(19) United States
(12) Patent Application Publication
(10) Pub. No.: US 2026/0318615 A1
(43) Pub. Date: Oct. 15, 2026

(54) MIXING-TYPE HEAT EXCHANGER

(71) Applicant: ASK CO.LTD., Jeonju-si (KR)

(72) Inventors: Tae Hee KIM, Yongin-si (KR); Seung Won JEOUNG, Jeonju-si (KR); Chang Son CHOI, Yongin-si (KR)

(21) Appl. No.: 19/681,693

(22) Filed: May 19, 2026

Related U.S. Application Data
(63) Continuation of application No. PCT/KR2024/019002, filed on Nov. 27, 2024.

(30) Foreign Application Priority Data
Jan. 12, 2024 (KR) 10-2024-0005684

(51) Int. Cl. F28D 21/00; B01F 23/20; B01F 25/00; B01F 25/431; B01F 35/90

(52) U.S. Cl. CPC F28D 21/00; B01F 23/291; B01F 25/4319; B01F 2025/932; B01F 2035/99; F28D 2021/0052

(57) ABSTRACT

Proposed is a mixing-type heat exchanger which can completely vaporize liquid droplet aerosol and prevent liquefaction of vapor to prevent generation of contaminant particles in a thin film deposition process of a semiconductor. The mixing-type heat exchanger may include a heat exchange unit, which comprises a plurality of heat exchange units which are formed with a multi-flow path structure and vertically mix and heat liquid droplet aerosol of a liquid precursor and vapor generated by vaporizing the aerosol, and has formed therein an inlet through which the liquid droplet aerosol and the vapor are introduced and an outlet through which the vapor is discharged. The mixing-type heat exchanger may also include a heater unit which is positioned on the outer circumferential surface of the heat exchange unit and heats the heat exchange unit.

### CROSS-REFERENCE TO RELATED APPLICATIONS

This is a continuation application of International Application No. PCT/KR2024/019002 filed on Nov. 27, 2024, which claims under 35 U.S.C. § 119(e) the benefit of Korean Patent Application No. KR 10-2024-0005684 filed on Jan. 12, 2024, the entire contents of each of which are incorporated by reference herein.

### STATEMENT REGARDING GOVERNMENT SPONSORED RESEARCH OR DEVELOPMENT

This disclosure was supported by the project listed in [Table 1] below.

TABLE 1

| Project Number | 00434116 |
|---|---|
| Ministry | Ministry of Trade, Industry and Energy |
| Managing | Korea Institute for Advancement of Technology |
| Agency | (KIAT) |
| Research | Material & Component Technology Innovation (Mass |
| Program | Production Performance Evaluation Support) |
| Research | Mass Production Performance Evaluation of DLI |
| Project Title | (Direct Liquid Injection) Vaporizer for TEOS |
| | Deposition Process |
| Performing | ASK Co., Ltd. |
| Organization | |
| Research Period | 2024 May 1-2025 Apr. 30 |
| Project Number | RS-2024-00508767 |
| Ministry | Ministry of SMEs and Startups |
| Managing | Korea Technology and Information Promotion Agency |
| Agency | for SMEs |
| Research | TIPS R&D Program |
| Program | |
| Research | Development of an integrated Vapor Delivery System |
| Project Title | for vaporizing liquid precursors for semiconductor |
| | ALD and CVD processes |
| Performing | ASK Co., Ltd. |
| Organization | |
| Research Period | 2024 Sep. 1-2026 Aug. 31 |

| | |
|---|---|
| Project Number | RS-2026-25531281 |
| Ministry | Ministry of Science and ICT |
| Managing Agency | Korea Innovation Cluster |
| Research | PoC Support Program through Strategic |
| Program | Cooperation |
| Research | Development and Evaluation of a domestically |
| Project Title | produced vaporizer module for mass production |
| | of DIPAS liquid precursor for semiconductor |
| | and display ALD processes. |
| Performing | ASK Co., Ltd. |
| Organization | |
| Research Period | 2026 Apr. 1-2027 Dec. 31 |

### BACKGROUND

### Technical Field

The present disclosure relates to a heat exchange device for a vaporizer used for thin-film deposition of semiconductor devices, and more specifically, to a hybrid heat exchanger positioned between a vaporizer and a chamber to completely vaporize droplet aerosols that have not been vaporized in the vaporizer or droplet aerosols formed by the liquefaction of vapor vaporized in the vaporizer while flowing to the chamber.

### Description of Related Technology

In semiconductor device and display manufacturing processes, a thin-film deposition process using a liquid precursor is generally performed. The thin-film deposition process may be performed by converting a droplet aerosol, which is obtained by finely dividing a liquid precursor, into a vapor state through a vaporizer, supplying the vapor into a chamber, and depositing the vapor onto a substrate within the chamber.

### SUMMARY

One aspect is a hybrid heat exchanger that prevents the generation of contamination particles in a thin-film deposition process of a semiconductor by completely vaporizing droplet aerosols and preventing the liquefaction of vapor.

Another aspect is a hybrid heat exchanger that includes a heat exchange section including a plurality of heat exchange units formed in a multi-channel structure to heat droplet aerosols of a liquid precursor and vapor vaporized from the droplet aerosols while mixing the droplet aerosols and the vapor in vertical directions, wherein an inlet for introducing the droplet aerosols and the vapor and an outlet for discharging the vapor are formed in the heat exchange section; and a heater section positioned on an outer circumferential surface of the heat exchange section to heat the heat exchange section.

The heat exchange section may include a first heat exchange unit formed in the multi-channel structure, configured to move the droplet aerosols and the vapor introduced through the centrally formed inlet in vertical directions and from a center toward an outer side, and to mix and heat the droplet aerosols and the vapor; a second heat exchange unit formed below the first heat exchange unit in the multi-channel structure vertically symmetrical to the first heat exchange unit, configured to move the droplet aerosols and the vapor that have passed through the first heat exchange unit in vertical directions and from the outer side toward the center, and to mix and heat the droplet aerosols and the vapor to discharge through the centrally formed outlet; and a first mixing zone formed between the first and second heat exchange units, allowing the droplet aerosols and the vapor discharged from the outer side of the first heat exchange unit to be mixed with each other and introduced into the outer side of the second heat exchange unit.

The first heat exchange unit may include a first flow path including a tube positioned at the center of the heat exchange section, an upper part of which is connected to the inlet, through which the droplet aerosols and the vapor introduced through the inlet move downward; a second flow path including a plurality of tubes surrounding an outside of the first flow path, through which the droplet aerosols and the vapor that have passed through the first flow path move upward; a third flow path including a plurality of tubes surrounding an outside of the second flow path and positioned at the outer side of the heat exchange section, through which the droplet aerosols and the vapor that have passed through the second flow path move downward; a second mixing zone formed below the first and second flow paths, allowing the droplet aerosols and the vapor that have passed through the first flow path to be mixed again and then introduced into the second flow path; and a third mixing zone formed above the second and third flow paths, allowing the droplet aerosols and the vapor that have passed through the second flow path to be mixed again and then introduced into the third flow path.

The second heat exchange unit may include a fourth flow path including a plurality of tubes positioned at the outer side of the heat exchange section, an upper part of which is connected to the first mixing zone, through which the droplet aerosols and the vapor that have passed through the first mixing zone move downward; a fifth flow path including a plurality of tubes surrounded by the fourth flow path, through which the droplet aerosols and the vapor that have passed through the fourth flow path move upward; a sixth flow path including a tube surrounded by the fifth flow path and positioned at the center of the heat exchange section, through which the droplet aerosols and the vapor that have passed through the fifth flow path move downward and are discharged to the outlet connected to a lower part thereof; a fourth mixing zone formed below the fourth and fifth flow paths, allowing the droplet aerosols and the vapor that have passed through the fourth flow path to be mixed again and then introduced into the fifth flow path; and a fifth mixing zone formed above the fifth and sixth flow paths, allowing the droplet aerosols and the vapor that have passed through the fifth flow path to be mixed again and then introduced into the sixth flow path.

The heat exchanger according to the present disclosure includes a heat exchange unit formed in a multi-channel structure, thereby increasing the surface area where droplet aerosols and vapor are in contact with the flow paths, and increasing the residence time of the droplet aerosols and vapor within the heat exchange unit to supply a large amount of thermal energy.

The heat exchanger according to the present disclosure includes a heat exchange unit that allows droplet aerosols and vapor to move vertically and mix with each other, thereby uniformly supplying thermal energy to the droplet aerosols and vapor.

Furthermore, the heat exchanger according to the present disclosure includes a mixing zone formed between a plurality of heat exchange units, allowing the droplet aerosols and vapor that have passed through each heat exchange unit to be mixed again.

In other words, the heat exchanger according to the present disclosure is positioned between the vaporizer and the chamber, and completely vaporizes droplet aerosols that have not been vaporized in the vaporizer or droplet aerosols formed by the liquefaction of vapor while the vapor flows to the chamber, thereby preventing the liquefaction of the vapor and preventing the generation of contamination particles in the thin-film deposition process.

### BRIEF DESCRIPTION OF THE DRAWINGS

FIG. 1 is a view illustrating a longitudinal cross-section of a heat exchanger according to an embodiment of the present disclosure.

FIG. 2 is a view illustrating a transverse cross-section of a heat exchanger according to an embodiment of the present disclosure.

### DETAILED DESCRIPTION

At this time, there may exist droplet aerosols that have not been vaporized due to heat loss in the vaporizer, or vapor may be liquefied while flowing through a flow path from the vaporizer to the chamber. Such droplet aerosols can cause contamination particles in the thin-film deposition process.

To prevent the generation of contamination particles in the thin-film deposition process, a method of supplying thermal energy to droplet aerosols and vapor by winding a heating wire around a flow path has been known. In particular, this method supplies a large amount of thermal energy to droplet aerosols and vapor in a short time by forming the flow path out of a metal with high thermal conductivity.

However, since droplet aerosols and vapor pass through the flow path rapidly, it is difficult to sufficiently supply thermal energy to the droplet aerosols and vapor that are not in contact with the flow path compared to those that are in contact with the flow path, and as a result, some droplet aerosols may not be completely vaporized and liquefaction of the vapor may occur. In order to prevent this issue, methods of heating the flow path to a high temperature or narrowing the diameter of the flow path to increase the contact surface area between the droplet aerosols/vapor and the flow path have been proposed. Such methods can supply a large amount of thermal energy to the droplet aerosols and vapor, thereby ensuring the complete vaporization of the droplet aerosols and preventing the liquefaction of the vapor. However, when applied to actual process equipment, there exists a problem of inefficiency due to increased process design costs, maintenance costs, and management costs.

Therefore, there is a need for the development of a device capable of more efficiently vaporizing droplet aerosols completely and preventing the liquefaction of vapor.

It should be noted that in the following description, only the parts necessary for understanding embodiments of the present disclosure are described, and the description of other parts will be omitted to the extent that it does not deviate from the subject matter of the present disclosure.

The terms or words used in the following description and claims should not be interpreted as limited to their usual or lexical meanings, and should be interpreted as meanings and concepts that conform to the technical idea of the present disclosure based on the principle that the inventor can appropriately define the concept of the term in order to explain his or her own invention in the best way. Therefore, embodiments disclosed in the description and configurations illustrated in the drawings are merely preferred embodiments of the present disclosure, and do not represent all of the technical idea of the present disclosure, so it should be understood that there may be various equivalents and modifications that can replace them at the time of this application.

Now, embodiments of the present disclosure will be described in detail with reference to the accompanying drawings.

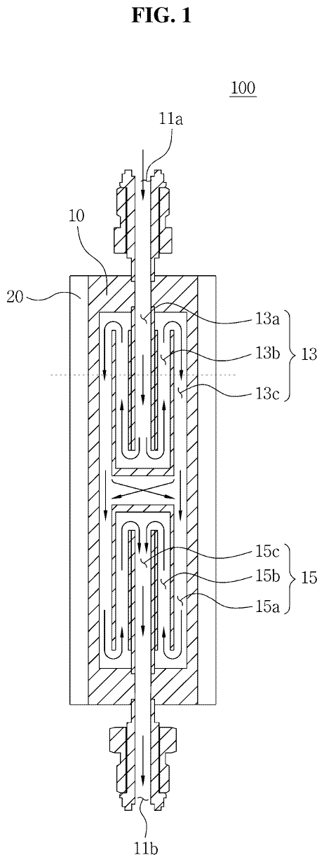

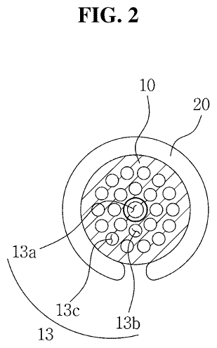

FIG. 1 is a view illustrating a longitudinal cross-section of a heat exchanger according to an embodiment of the present disclosure, and FIG. 2 is a view illustrating a transverse cross-section of a heat exchanger according to an embodiment of the present disclosure.

Referring to FIGS. 1 and 2, the heat exchanger 100 according to an embodiment is a heat exchange device for a vaporizer used for thin-film deposition of semiconductor devices. The heat exchanger 100 includes a heat exchange section 10 and a heater section 20. The heat exchange section 10 includes a plurality of heat exchange units formed in a multi-channel structure to heat droplet aerosols of a liquid precursor and vapor vaporized from the droplet aerosols while mixing them in vertical directions. The heater section 20 is disposed on an outer circumferential surface of the heat exchange section 10 to heat the heat exchange section 10.

In semiconductor device and display manufacturing processes, a thin-film deposition process using a liquid precursor is generally performed. The thin-film deposition process may be performed by converting a droplet aerosol, which is obtained by finely dividing a liquid precursor, into a vapor state through a vaporizer, supplying the vapor into a chamber, and depositing the vapor onto a substrate within the chamber. However, droplet aerosols that have not been vaporized in the vaporizer, or droplet aerosols formed by the liquefaction of vapor due to heat loss occurring while the vapor flows from the vaporizer to the chamber, may cause contamination particles in the thin-film deposition process.

Therefore, the heat exchanger 100 according to the embodiment is positioned between the vaporizer and the chamber, thereby completely vaporizing droplet aerosols that have not been vaporized in the vaporizer or droplet aerosols formed by the liquefaction of vapor while flowing to the chamber, and preventing liquefaction of the vapor to prevent the generation of contamination particles during the thin-film deposition process.

Hereinafter, the configuration of the heat exchanger 100 according to the embodiment will be described in more detail.

The heat exchange section 10 may include an inlet 11a connected to the vaporizer through which droplet aerosols that have not been vaporized in the vaporizer and vapor vaporized in the vaporizer are introduced, and an outlet 11b connected to the chamber to discharge the vapor into the chamber.

Furthermore, the heat exchange section 10 may include a plurality of heat exchange units. For example, the heat exchange section 10 may include a first heat exchange unit 13, a second heat exchange unit 15 formed below the first heat exchange unit 13, and a first mixing zone 14 positioned between the first and second heat exchange units 13 and 15.

The first and second heat exchange units 13 and 15 are formed in a multi-channel structure to heat the droplet aerosols and vapor while mixing them in vertical directions. The shapes of the first and second heat exchange units 13 and 15 are not particularly limited, but they are preferably cylindrical. In addition, the material of the first and second heat exchange units 13 and 15 is not particularly limited, but they are preferably formed of a metal with high thermal conductivity.

Generally, droplet aerosols and vapor can be supplied with thermal energy in proportion to the surface area in contact with the flow path. Therefore, by including the first and second heat exchange units 13 and 15 formed in a multi-channel structure, the heat exchanger 100 according to the embodiment enables an increase in the surface area where the droplet aerosols and vapor are in contact with the flow path and extends the residence time of the droplet aerosols and vapor within the first and second heat exchange units 13 and 15, thereby supplying a large amount of thermal energy. Through this, the droplet aerosols can be completely vaporized and the liquefaction of the vaporized vapor can be prevented.

Specifically, the first heat exchange unit 13 can heat the droplet aerosols and vapor introduced through the inlet 11a while mixing them in vertical directions and from the center to the outside. The first heat exchange unit 13 may include a first flow path 13a, a second flow path 13b, a third flow path 13c, a second mixing zone 13d, and a third mixing zone 13e.

Here, the first flow path 13a is a tube positioned at the center of the heat exchange section 10, the second flow path 13b is a plurality of tubes surrounding the outside of the first flow path 13a, and the third flow path 13c is a plurality of tubes surrounding the outside of the second flow path 13b. The second mixing zone 13d is formed below the first and second flow paths 13a and 13b to allow the droplet aerosols and vapor that have passed through the first flow path 13a to be mixed with each other and introduced into the second flow path 13b. In addition, the third mixing zone 13e is formed above the second and third flow paths 13b and 13c to allow the droplet aerosols and vapor that have passed through the second flow path 13b to be mixed with each other and introduced into the third flow path 13c.

For example, the droplet aerosols and vapor may move downward through the first flow path 13a, the upper part of which is connected to the inlet 11a, and flow into the second mixing zone 13d. The droplet aerosols and vapor introduced into the second mixing zone 13d collide with the bottom of the second mixing zone 13d, are mixed with each other, move from the center to the outside, and flow into the second flow path 13b. The droplet aerosols and vapor introduced into the second flow path 13b move upward through the second flow path 13b and flow into the third mixing zone 13e. The droplet aerosols and vapor introduced into the third mixing zone 13e collide with the top of the third mixing zone 13e, are mixed with each other, move from the center to the outside, and flow into the third flow path 13c. The droplet aerosols and vapor introduced into the third flow path 13c may move downward through the third flow path 13c.

Although the multi-channel structure of the first heat exchange unit 13 including the first to third flow paths 13a, 13b, and 13c increases the contact surface area, it remains difficult to supply sufficient thermal energy to the droplet aerosols and vapor flowing through the flow paths without contacting the walls.

Therefore, the first heat exchange unit 13 is designed to induce vertical movement and mixing of the droplet aerosols and vapor, thereby uniformly supplying thermal energy to the droplet aerosols and vapor, through which the droplet aerosols can be completely vaporized and the liquefaction of the vaporized vapor can be prevented.

Furthermore, the first mixing zone 14 is formed between the first and second heat exchange units 13 and 15, and allows the droplet aerosols and vapor that have passed through the first heat exchange unit 13 to be mixed again and then introduced into the second heat exchange unit 15.

The second heat exchange unit 15 can heat the droplet aerosols and vapor that have passed through the first heat exchange unit 13 while mixing them in vertical directions and from the outside to the center, and has a multi-channel structure similar to that of the first heat exchange unit 13. Specifically, the second heat exchange unit 15 may include a fourth flow path 15a, a fifth flow path 15b, a sixth flow path 15c, a fourth mixing zone 15d, and a fifth mixing zone 15e.

Here, the fourth flow path 15a is a plurality of tubes positioned below the third flow path 13c, the fifth flow path 15b is a plurality of tubes positioned inward of the fourth flow path 15a, and the sixth flow path 15c is a tube positioned inward of the fifth flow path 15b. The fourth mixing zone 15d is formed below the fourth and fifth flow paths 15a and 15b to allow the droplet aerosols and vapor that have passed through the fourth flow path 15a to be mixed with each other and introduced into the fifth flow path 15b. In addition, the fifth mixing zone 15e is formed above the fifth and sixth flow paths 15b and 15c to allow the droplet aerosols and vapor that have passed through the fifth flow path 15b to be mixed with each other and introduced into the sixth flow path 15c.

For example, the droplet aerosols and vapor may move downward through the fourth flow path 15a, the upper part of which is connected to the first mixing zone 14, and flow into the fourth mixing zone 15d. The droplet aerosols and vapor introduced into the fourth mixing zone 15d collide with the bottom of the fourth mixing zone 15d, are mixed with each other, move from the outside to the center, and flow into the fifth flow path 15b. The droplet aerosols and vapor introduced into the fifth flow path 15b move upward through the fifth flow path 15b and flow into the fifth mixing zone 15e. The droplet aerosols and vapor introduced into the fifth mixing zone 15e collide with the top of the fifth mixing zone 15e, are mixed with each other, move from the outside to the center, and flow into the sixth flow path 15c. The droplet aerosols and vapor introduced into the sixth flow path 15c may move downward through the sixth flow path 15c.

Therefore, the second heat exchange unit 15 is designed to induce vertical movement and mixing of the droplet aerosols and vapor, thereby uniformly supplying thermal energy to the droplet aerosols and vapor, through which the droplet aerosols can be completely vaporized and the liquefaction of the vaporized vapor can be prevented.

The heater section 20 is positioned on the outer circumferential surface of the heat exchange section 10 and is configured to surround and heat the heat exchange section 10, thereby vaporizing the droplet aerosols existing within the heat exchange section 10. For example, the heater section 20 may be a band heater, but it is not limited thereto.

In addition, the heat exchanger according to the present disclosure may be in a form in which a plurality of the heat exchangers 100 according to the embodiment are connected in series.

Meanwhile, the embodiments disclosed in the description and drawings are merely specific examples presented to help understanding and are not intended to limit the scope of the present disclosure. It is apparent to those skilled in the art to which the present disclosure pertains that other modifications based on the technical idea of the present disclosure can be implemented in addition to the embodiments disclosed herein.

1. A hybrid heat exchanger comprising:
a heat exchange section including a plurality of heat exchange units formed in a multi-channel structure to heat droplet aerosols of a liquid precursor and vapor vaporized from the droplet aerosols while mixing the droplet aerosols and the vapor in vertical directions, wherein an inlet for introducing the droplet aerosols and the vapor and an outlet for discharging the vapor are formed in the heat exchange section; and
a heater section positioned on an outer circumferential surface of the heat exchange section to heat the heat exchange section,
wherein the heat exchange section comprises:
a first heat exchange unit formed in the multi-channel structure, configured to move the droplet aerosols and the vapor introduced through the centrally formed inlet in vertical directions and from a center toward an outer side, and to mix and heat the droplet aerosols and the vapor;
a second heat exchange unit formed below the first heat exchange unit in the multi-channel structure vertically symmetrical to the first heat exchange unit, configured to move the droplet aerosols and the vapor that have passed through the first heat exchange unit in vertical directions and from the outer side toward the center, and to mix and heat the droplet aerosols and the vapor to discharge through the centrally formed outlet; and
a first mixing zone formed between the first and second heat exchange units, allowing the droplet aerosols and the vapor discharged from the outer side of the first heat exchange unit to be mixed with each other and introduced into the outer side of the second heat exchange unit.

2. The hybrid heat exchanger of claim 1, wherein the first heat exchange unit comprises:
a first flow path including a tube positioned at the center of the heat exchange section, an upper part of which is connected to the inlet, through which the droplet aerosols and the vapor introduced through the inlet move downward;
a second flow path including a plurality of tubes surrounding an outside of the first flow path, through which the droplet aerosols and the vapor that have passed through the first flow path move upward;
a third flow path including a plurality of tubes surrounding an outside of the second flow path and positioned at the outer side of the heat exchange section, through which the droplet aerosols and the vapor that have passed through the second flow path move downward;
a second mixing zone formed below the first and second flow paths, allowing the droplet aerosols and the vapor that have passed through the first flow path to be mixed again and then introduced into the second flow path; and
a third mixing zone formed above the second and third flow paths, allowing the droplet aerosols and the vapor that have passed through the second flow path to be mixed again and then introduced into the third flow path.

3. The hybrid heat exchanger of claim 1, wherein the second heat exchange unit comprises:
a fourth flow path including a plurality of tubes positioned at the outer side of the heat exchange section, an upper part of which is connected to the first mixing zone, through which the droplet aerosols and the vapor that have passed through the first mixing zone move downward;
a fifth flow path including a plurality of tubes surrounded by the fourth flow path, through which the droplet aerosols and the vapor that have passed through the fourth flow path move upward;
a sixth flow path including a tube surrounded by the fifth flow path and positioned at the center of the heat exchange section, through which the droplet aerosols and the vapor that have passed through the fifth flow path move downward and are discharged to the outlet connected to a lower part thereof;
a fourth mixing zone formed below the fourth and fifth flow paths, allowing the droplet aerosols and the vapor that have passed through the fourth flow path to be mixed again and then introduced into the fifth flow path; and
a fifth mixing zone formed above the fifth and sixth flow paths, allowing the droplet aerosols and the vapor that have passed through the fifth flow path to be mixed again and then introduced into the sixth flow path.
